(19) United States
(12) Patent Application Publication
(10) Pub. No.: US 2011/0103025 A1
(43) Pub. Date: May 5, 2011

(54) MODULAR ELECTRONIC SYSTEM

(76) Inventors: Daniel P. Ross, Maplewood, MN (US); Greg T. Mrozek, Brooklyn Park, MN (US); Christopher M. Lange, New Brighton, MN (US); William C. Scherer, Coon Rapids, MN (US)

(21) Appl. No.: 13/001,557

(22) PCT Filed: Jun. 11, 2009
(86) PCT No.: PCT/US09/47037

§ 371 Date: Dec. 27, 2010

Related U.S. Application Data
(60) Provisional application No. 61/077,328, filed on Jul. 1, 2008.

(51) Int. Cl. H05K 7/00

(52) U.S. Cl. 361/728

(57) ABSTRACT

Off-the-shelf electronic packages eliminate the much of the need for hardware redesign for each product. The base unit has a base plastic housing and a power/communication board. The component module is comprised of a mid-section plastic housing, a common board, a component board, panels with connectors and a housing cover. The component board is unique board to each platform and could be, for example, a fluid control module, a low power temperature control module, a gateway module, a USB module, etc.

### TECHNICAL FIELD

This application claims the benefit of U.S. Application Ser. No. 61/077,328, filed Jul. 1, 2008, the contents of which are hereby incorporated by reference.

### BACKGROUND ART

In the control of fluid handling and dispensing systems and similar related control systems, traditionally such systems have utilized bespoke controllers for each particular product or system which has proven costly, particularly for products with low volumes.

### DISCLOSURE OF THE INVENTION

The basis of the instant invention is to have off-the-shelf electronic packages to eliminate the need for “common” hardware design. This will also increase the quantity of the shared “common” components of these modules thereby decreasing the costs of the electronic packages as a whole: The modular platform is based on these components. The base unit has a base plastic housing and a power/communication board. The component module is comprised of a mid-section plastic housing, a common board, a component board, panels with connectors and a housing cover. The component board is unique board to each platform and could be, for example, a fluid control module, a low power temperature control module, a gateway module, a USB module, etc.

This design will eliminate the need to layout communications, power, common componentry, or the need to develop a new package to fit a new electronics board into, thereby expediting the development time of future electronics. The layout for these components can be approximately 60% of the development time of an electronic component.

This design will also reduce downtime due to a failing board. The component board, along with the common electronics boards (boards that pose the most risk to failure) are isolated in their own module, and can be quickly replaced with another module. The only tool needed by an end user would be an allen wrench to replace a module.

These and other objects and advantages of the invention will appear more fully from the following description made in conjunction with the accompanying drawings wherein like reference characters refer to the same or similar parts throughout the several views.

### BRIEF DESCRIPTION OF DRAWINGS

FIG. 1 is an exploded view of a component module of the instant invention.

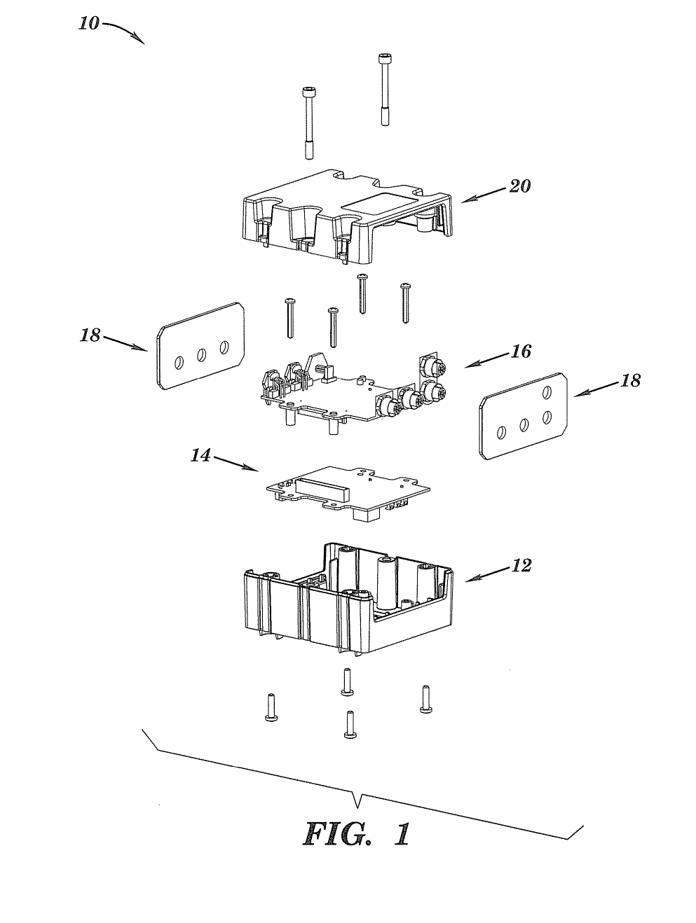

FIG. 2 is a perspective view of an assembled component module of the instant invention.

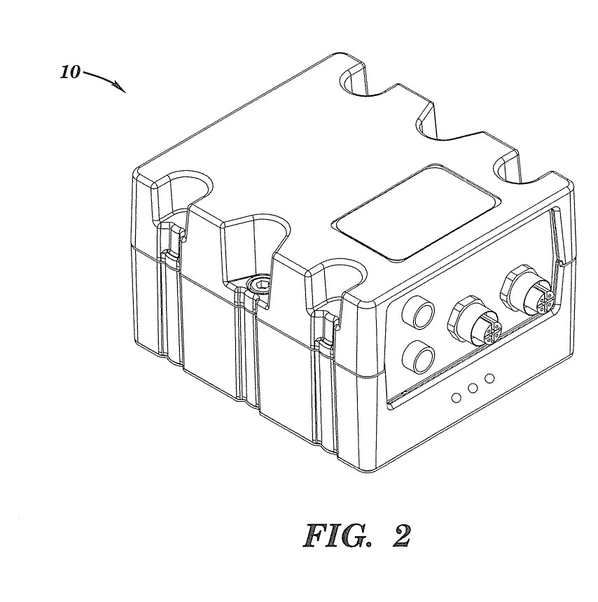

FIG. 3 is a perspective view of an assembled base module of the instant invention.

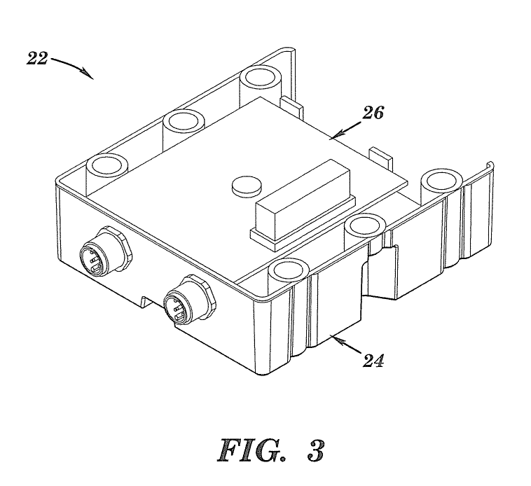

### BEST MODE FOR CARRYING OUT THE INVENTION

The basis of the instant invention is to have off-the-shelf electronic packages to eliminate the need for “common” hardware design. This will also increase the quantity of the shared “common” components of these modules thereby decreasing the costs of the electronic packages as a whole: The modular platform is based on these components. The base unit 22 has a base plastic housing 24 and a power/communication board 26. The component module 10 is comprised of a mid-section plastic housing 12, a common board 14, a component board 16, panels 18 with connectors and a housing cover 20. The component board 16 is unique board to each platform and could be, for example, a fluid control module, a low power temperature control module, a gateway module, a USB module, etc.

This design will eliminate the need to layout communications, power, common componentry, or the need to develop a new package to fit a new electronics board into, thereby expediting the development time of future electronics. The layout for these components can be approximately 60% of the development time of an electronic component.

This design will also reduce downtime due to a failing board. The component board, along with the common electronics boards (boards that pose the most risk to failure) are isolated in their own module, and can be quickly replaced with another module. The only tool needed by an end user would be an allen wrench to replace a module.

It is contemplated that various changes and modifications may be made to the modular system without departing from the spirit and scope of the invention as defined by the following claims.

1. A control module comprising:
a base unit comprising a housing and a power/communication board; and
a component module connected to said base unit and comprising a housing, a common board, a component board, and a housing cover.

2. The control module of claim 1 wherein said component board is a unique board selected from the group consisting of a fluid control module, a low power temperature control module, a gateway module and a USB module.
